(19) United States
(12) Patent Application Publication
(10) Pub. No.: US 2008/0094084 A1
(43) Pub. Date: Apr. 24, 2008

(54) MULTI-LAYER ELECTRIC PROBE AND FABRICATING METHOD THEREOF

(75) Inventors: Meng-Chi Huang, Fongshan City (TW); Min-Chieh Chou, Taipei City (TW); Fuh-Yu Chang, Jhubel City (TW); Ching-Ping Wu, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignees: Industrial Technology Research Institute, Hsinchu (TW); SCH ELECTRONIC CO., LTD., TAIPEI (TW)

(21) Appl. No.: 11/616,892

(22) Filed: Dec. 28, 2006

(30) Foreign Application Priority Data
Oct. 24, 2006 (TW) 95139153

(51) Int. Cl. G01R 31/02; H01R 43/00

(52) U.S. Cl. 324/754; 29/825

(57) ABSTRACT

A multi-layer electric probe, suitable for testing a to-be-tested device, includes a first strip layer and a second strip layer. The first strip layer has a first conductivity and a first mechanical strength. The second strip layer has a second conductivity and a second mechanical strength. The first strip layer and the second strip layer are solidly adhered together as a structural body so as to produce at least one of the desired capabilities of enduring current and mechanical strength. The multi-layer electric probe can further include at least a third strip layer having the capability of enduring current and the desired mechanical strength.

### CROSS-REFERENCE TO RELATED APPLICATION

This application claims the priority benefit of Taiwan application serial no. 95139153, filed Oct. 24, 2006. All disclosure of the Taiwan application is incorporated herein by reference.

### BACKGROUND OF THE INVENTION

1. Field of the Invention

The present invention relates to a test probe, and more particularly to an electric probe for testing devices.

2. Description of Related Art

Probes have been widely used in the fabrication and testing of the integrated circuits for quite some time. To increase the packaging yield, naked dies having different kinds of problems are normally scrapped or removed for subsequent repair by performing functional tests using the probes.

The commonly used probes originate, for example, from the basic design disclosed in U.S. Pat. No. 4,027,935 in which a cobra probe is formed by mechanically working on a small round rod of material. FIG. 1 is a sketch of a conventional cobra probe structure. The conventional cobra probe as shown in FIG. 1 mainly includes a test terminal 102 disposed on an operating board 100 through a rotatable pivot. The body 104 of the probe is connected to the pivot of the test terminal 102. The body 104 has a curved shape to provide the flexibility and deformation required by the testing operation. Furthermore, a contact terminal 108 disposed on another operating board 106 can be used to contact a to-be-tested device (not shown). Through the body 104 of the probe, a stress is applied to the to-be-tested device. In addition, a current or a voltage, for example, can be applied to the to-be-tested device through the probe.

For probes having this type of structure, each of the probes has to be individually worked so that considerable time has to be spent on their production. Moreover, with progress in integrated circuit processing technology, line widths and gaps are reduced as well. Thus, the probes have to face the limitations caused by the shrinking of probe diameter.

Other conventional technique for forming the probes includes chemical etching. One major advantage of this technique is its capability for fabricating probes having a variety of geometric shapes. However, due to material restrictions, for example, BeCu alloy, only a single metal can be used in the fabrication. Although the probe is still capable of enduring high current, it has an inferior mechanical strength and a shorter life span and is more expensive to produce.

Most probes constructed from a single component, for example, Ni, NiCo alloy, NiMn alloy, have insufficient capability for enduring high current. In addition, heat may be easily accumulated, result in shortening the life of the probes. Moreover, the probes frequently encounter some restrictions when testing high frequency integrated circuits (IC).

### SUMMARY OF THE INVENTION

Accordingly, the present invention provides a multi-layer electric probe having the capability of enduring high current and the desired mechanical strength and suitable for testing a to-be-tested device.

The present invention provides a method of fabricating a multi-layer electric probe such that the manufactured multi-layer electric probe has the capability of enduring high current and the desired mechanical strength.

The invention provides a multi-layer electric probe structure. The multi-layer electric probe includes a first strip layer and a second strip layer. The first strip layer has a first conductivity and a first mechanical strength. The second strip layer has a second conductivity and a second mechanical strength. The first strip layer and the second strip layer are solidly adhered together as a structural body so as to produce a desired conductivity and a desired mechanical strength. Moreover, the multi-layer electric probe can further include at least a third strip layer to produce the desired conductivity and the desired mechanical strength.

The present invention also provides an alternative multi-layer electric probe suitable for testing a to-be-tested device. The multi-layer electric probe includes a measuring section and a body section. The body section and the measuring section are mechanically connected, wherein one end of the body section is used for contacting the to-be-tested device and applying at least one testing parameter. The body section at least includes a firs strip layer having a first conductivity and a first mechanical strength and a second strip layer having a second conductivity and a second mechanical strength. The first strip layer and the second strip layer are solidly adhered to form a structural body so as to produce at least one of the desired capabilities of enduring current and mechanical strength.

The present invention also provides a method of fabricating a multi-layer electric probe. The method includes forming a first strip layer. The first strip layer has a first conductivity and a first mechanical strength. Then, a second strip layer is solidly adhered to a surface of the first strip layer to form a structural body, wherein the second strip layer has a second conductivity and a second mechanical strength. The combination of the second conductivity and the second mechanical strength with the first conductivity and the first mechanical strength produces the desired capabilities of enduring current and mechanical strength.

Because the electric probe in the present invention has a multi-layer structure, a probe with the desired mechanical strength and the capability of enduring high current can be prepared.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a sketch of a conventional cobra probe structure.

FIG. 2A is a schematic structural cross-sectional view of a multi-layer electric probe according to an embodiment of the present invention.

FIG. 2B is a schematic cross-sectional view of the multi-layer electric probe in FIG. 2A.

FIGS. 3A through 3D are schematic diagrams showing the steps for fabricating a multi-layer electric probe according to an embodiment of the present invention.

FIGS. 4A through 4D are schematic diagrams showing the steps for fabricating a multi-layer electric probe according to another embodiment of the present invention.

FIGS. 5A, 5B, 6 and 7 are schematic diagrams showing the method for fabricating a multi-layer electric probe and some of the probes structures according to another embodiment of the present invention.

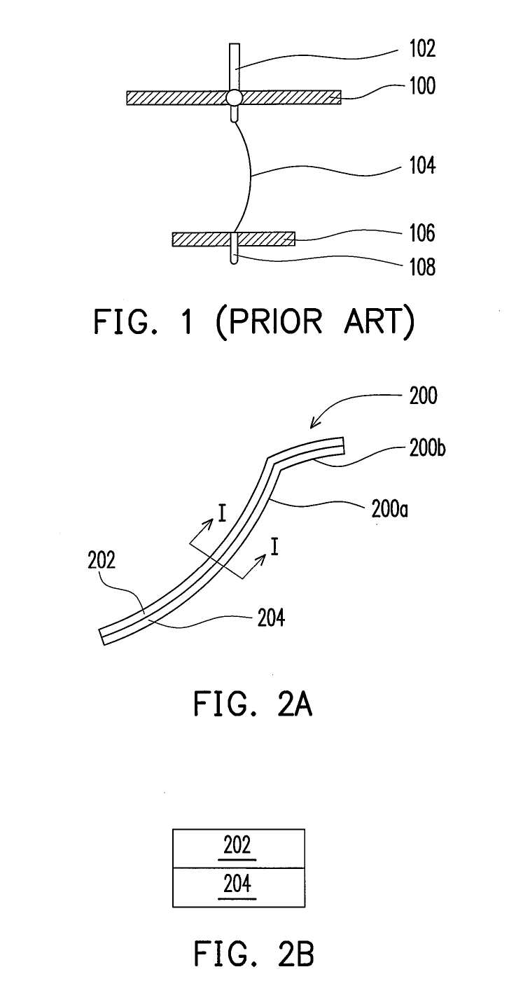

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

The present invention provides a multi-layer electric probe design having the capability of enduring high current and the desired mechanical strength. FIG. 2A is a schematic structural cross-sectional view of a multi-layer electric probe according to an embodiment of the present invention. FIG. 2B is a schematic cross-sectional view of the multi-layer electric probe in FIG. 2A. As shown in FIGS. 2A and 2B, the multi-layer electric probe 200 in the present embodiment is suitable for testing a to-be-tested device. The multi-layer electric probe 200, for example, includes a first strip layer 202 and a second strip layer 204. Here, the multi-layer electric probe 200 has a two-layer structure. However, according to the principle described below, the multi-layer electric probe 200 can have a structure with more than two layers. Meanwhile, for the foregoing two-layer structure, the first strip layer 202 has a first conductivity and a first mechanical strength and the second strip layer 204 has a second conductivity and a second mechanical strength. The first strip layer 202 and the second strip layer 204 are solidly adhered to form a structural body so as to produce the capability of enduring current and the desired mechanical strength.

According to the functional requirements, the multi-layer electric probe 200 can be divided into a body section 200a and a measuring section 200b, for example. The body section 200a can be designed to have a curve portion and one of the ends can be used to contact a to-be-tested device. The measuring portion 200b of the multi-layer electric probe 200 is connected with an external control unit and is responsible for applying testing signals and providing stress generated by the body, for example, the stress generated by elastic deformation to the to-be tested device. In other words, the multi-layer electric probe 200 shown in FIG. 2A is only a single structure. In actual applications, a plurality of probes may be assembled together and controlled by the external control unit. Since those with ordinary skill in the art can understand this aspect of the design, a detailed description is omitted.

The first strip layer 202 and the second strip layer 204 of the multi-layer electric probe 200 is fabricated using NiCo alloy and Cu, for example, with each layer having a predetermined thickness. Therefore, the mechanical strength of the multi-layer electric probe 200 can be adjusted. Moreover, by combining the conductivity of the first strip layer 202 and the second strip layer 204 and matching the thickness between the first strip layer 202 and the second strip layer 204, the desired conductivity and the capability of enduring high current can be produced. Because the multi-layer electric probe 200 is composed of several layers, the layers can be easily adjusted to produce the desired mechanical strength and the capability of enduring high current. In the following, an embodiment is provided to describe the method of fabricating a multi-layer electric probe 200. Obviously, the method of fabricating the multi-layer electric probe 200 is not limited to the one illustrated. In fact, any method capable of producing the multi-layer structure of the multi-layer electric probe 200 is applicable.

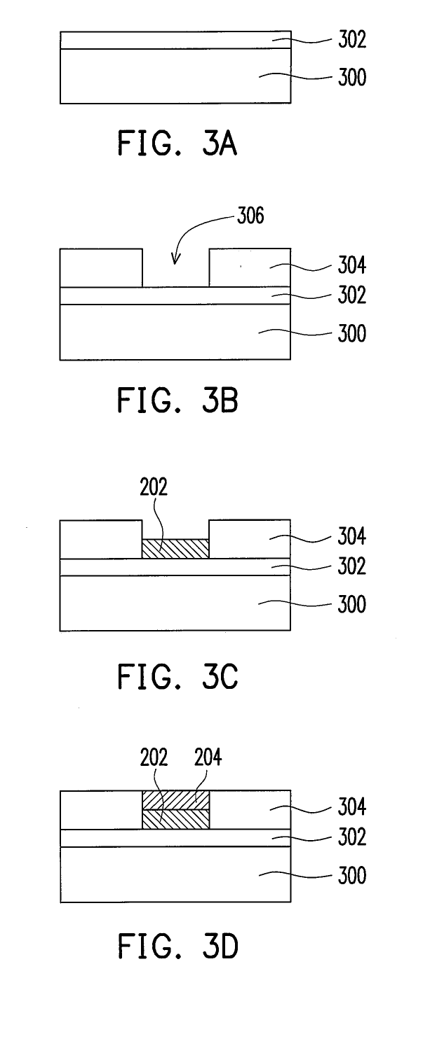

FIGS. 3A through 3D are schematic diagrams showing the steps for fabricating a multi-layer electric probe according to an embodiment of the present invention. As shown in FIG. 3A, a metal layer 302 is formed on a substrate 300. To be compatible to the semiconductor process, the substrate 300 is a silicon substrate and the metal layer 302 is a nickel layer formed in a deposition process, for example. Then, as shown in FIG. 3B, a photoresist layer 304 is formed on the metal layer 302 in a photolithographic process. The photoresist layer 304 has an opening 306 that exposes a portion of the metal layer 302. The pattern of the opening 306 in the vertical direction depends on the actual design.

As shown in FIG. 3C, the first strip layer 202 is formed on the metal layer 302 inside the opening 306 by performing an electro-forming process. The metal layer 302 mainly serves as an electrode for the electro-forming process. Hence, its material should be selected to correspond to the material of the first strip layer 202, a material that can be easily detached from the first strip layer 202 after the electro-forming process. The first strip layer 202 has a predetermined thickness.

As shown in FIG. 3D, the electro-forming process is applied to form a second strip layer 204 on the first strip layer 202. The second strip layer 204 is solidly adhered to the first strip layer 202 to form a structural body. The second strip layer 204, for example, completely fills the opening 306. As mentioned before, if more strip layers are desired, the same electro-forming process can be used to form strip layers of the desired thickness. Subsequently, the multi-layer structure can be detached to produce an embodiment of the multi-layer electric probe 200. The body section 200a and the measuring section 200b, for example, can be fabricated together simultaneously. The material constituting the first strip layer 202 and the second strip layer 204, for example, can be selected from NiCo alloy, NiMn alloy, Cu, Ni, Au, Ag, Co, W, W alloy and Ni alloy.

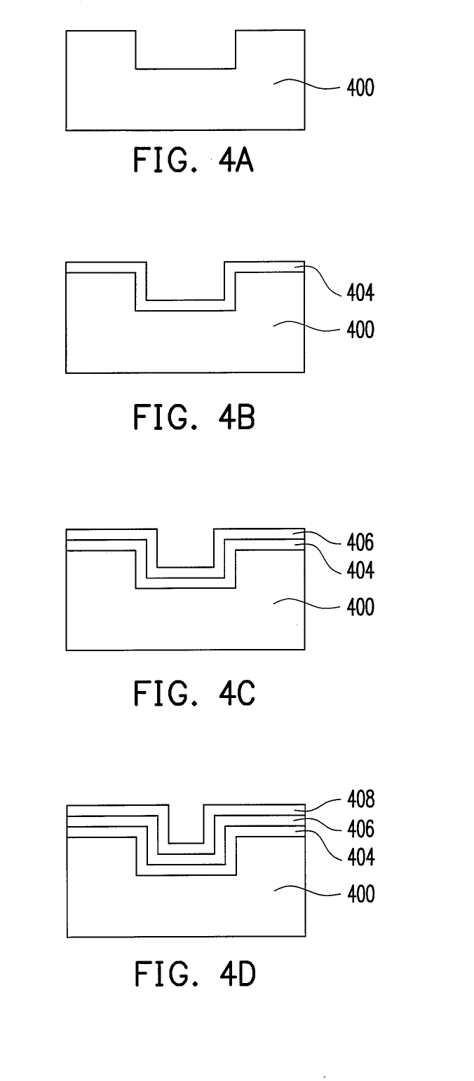

FIGS. 4A through 4D are schematic diagrams showing the steps for fabricating a multi-layer electric probe according to another embodiment of the present invention. As shown in FIG. 4A, photolithographic and etching processes are used to form a trench having a predefined pattern on a substrate, for example, a silicon substrate. A top view of the trench is shown in FIG. 2A and the trench has a curve main body section, for example.

As shown in FIG. 4B, similar to the metal layer 302 in FIG. 3A, a metal layer 404 is formed on the substrate 400 in a deposition process. As shown in FIG. 4C, an electro-forming process or a deposition process is performed to form a first metal layer 406 comprising a material and having a thickness set by the desired parameter. The material constituting the first metal layer 406 can be selected from the elements of NiCo alloy, NiMn alloy, Cu, Ni, Au, Ag, Co, W, W alloy and Ni alloy. Furthermore, the first metal layer 406 also has the desired thickness. Next, as shown in FIG. 4D, a similar method is used to form a second metal layer 408 though the material constituent is different from the first metal layer 406 so that a multi-layer structure is formed. Obviously, another layer may form on top if one desires. Then, a suitable portion of the metal layer 406 and the metal layer 408 is removed so that the portion remaining inside the trench area constitutes the multi-layer electric probe. Thus, the multi-layer electric probe has a cavity structure on a cross section. Although the cross-sectional structure in the present embodiment is different from the structure shown in FIG. 2B, a multi-layer effect is still produced.

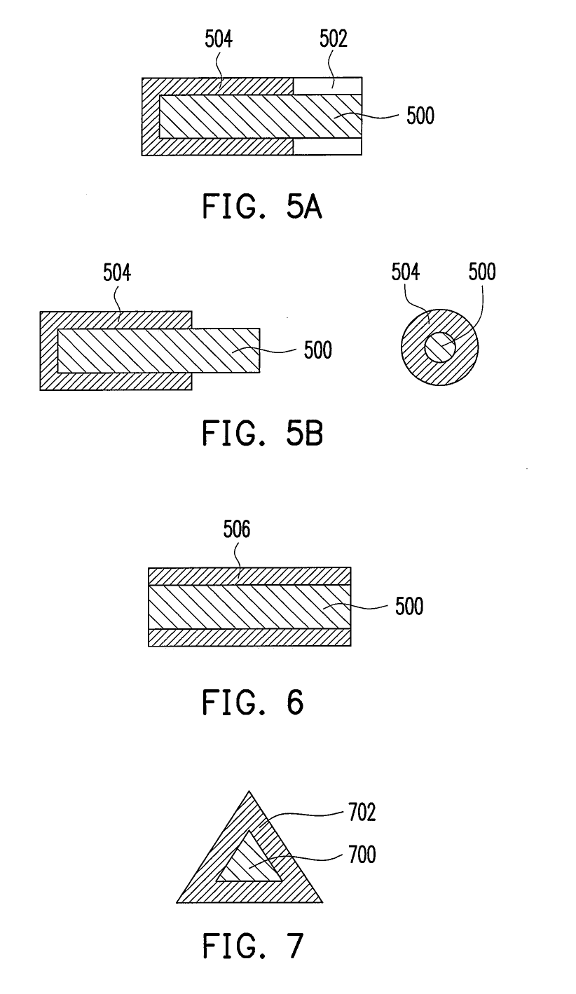

In other words, the multi-layer structure in the present invention can have different variations equally capable of producing the required effects in the present invention. FIGS. 5A, 5B, 6 and 7 are schematic diagrams showing the method for fabricating a multi-layer electric probe and some of the probes structures according to another embodiment of the present invention. These embodiments are fabricated using the electroplating method.

As shown in FIG. 5A, a first strip layer 500 is fabricated. The first strip layer 500 has the desired curve or length and predetermined cross section. The cross-sectional area of the first strip layer 500 can have a geometric shape in the form of a circle, a triangle or a polygon, for example. Then, using the first strip layer 500 as an electrode, an electroplating process is performed. According to the actual requirements, the second strip layer 504 to be plated on the first strip layer 500 may not need to cover the entire surface. Therefore, an insulating layer 502 may be formed over a portion of the first strip layer 500 so that the second strip layer 504 will not cover that portion of the surface when the electroplating process is performed.

As shown in FIG. 5B, the insulating layer 502 is removed. In the diagram on the left, the remaining second strip layer 504 covers a portion of the surface of the first strip layer 500. In the diagram on the right, the cross-section is a round geometric shape. On the other hand, as shown in FIG. 6, the second strip layer 506 may substantially cover the surface of the first strip layer 500 and, for example, covers the entire side surface of the strip layer 500. Furthermore, as shown in FIG. 7, the cross section of the first strip layer 700 and the second strip layer 702 is in the form of a triangle. It should be understood that the cross section could be some other geometric shape such as a polygon.

Furthermore, the first strip layer is not limited to the covering of only a second strip layer. According to the actual requirement, at least a third strip layer may be disposed over the first strip layer to cover the second strip layer and/or the first strip layer. This is one of the possible variations of the embodiment.

Generally, several embodiments have been provided as follows. According to an embodiment of the present invention, the first strip layer and the second strip layer in the multi-layer electric probe have a strip shape and use surface contact to form the structural body. Moreover, according to another embodiment, the first strip layer has a first thickness and the second strip layer has a second thickness for adjusting to the desired mechanical strength and the capability of enduring current.

According to an embodiment of the present invention, the foregoing multi-layer electric probe includes at least a third strip layer having a third conductivity and a third mechanical strength, and the third strip layer together with the first strip layer and second strip layer form the foregoing structural body.

According to an embodiment of the present invention, the first strip layer and the second strip layer of the foregoing multi-layer electric probe have a cross-sectional structure of a cavity-shape stack layer.

According to an embodiment of the present invention, the second strip layer of the foregoing multi-layer electric probe covers at least one portion of the first strip layer or substantially the entire surface of the first strip layer.

According to an embodiment of the present invention, the first strip layer of the foregoing multi-layer electric probe has a cross section of a geometric figure, for example, a circle, a triangle or a polygon.

According to an embodiment of the present invention, the first strip layer and the second strip layer of the foregoing multi-layer electric probe have at least one curve portion.

According to an embodiment of the present invention, the first strip layer and the second strip layer of the foregoing multi-layer electric probe are solidly adhered by performing an electro-forming process.

According to an embodiment of the present invention, the first strip layer and the second strip layer of the foregoing multi-layer electric probe are solidly adhered by performing an electroplating process.

The foregoing description is the structure of the multi-layer electric probe. Anyone skilled in the art should understand that a number of multi-layer electric probes are normally disposed on the surface of a carrier in an actual testing operation. Through the control of an external control unit, the probe carrier is moved and the required testing signals and stress are applied to the to-be-tested device. Here, a detailed description of the control is not elaborated.

The present invention particularly highlights the importance of multi-layer electric probe because a probe with a multi-layer structure can effectively promote mechanical strength and enduring current capability. Moreover, the multi-layer electric probe can be fabricated with an appropriate semiconductor process to shrink the cross-sectional dimension of the probe. Hence, the multi-layer electric probe can be used to test integrated circuits with a high level of integration.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A multi-layer electric probe, comprising:
a first strip layer, having a first conductivity and a first mechanical strength; and
a second strip layer, having a second conductivity and a second mechanical strength, wherein the first strip layer and the second strip layer are solidly adhered to form a structural body serving as a part of the multi-layer electric probe.

2. The multi-layer electric probe of claim 1, wherein the first strip layer and the second strip layer have a strip shape and form the structural body through surface contact.

3. The multi-layer electric probe of claim 1, wherein the first strip layer has a first thickness and the second strip layer has a second thickness.

4. The multi-layer electric probe of claim 1, further comprising at least a third strip layer having a third conductivity and a third mechanical strength, and forming the structural body together with the first strip layer and the second strip layer.

5. The multi-layer electric probe of claim 1, wherein the first strip layer and the second strip layer have a cross-sectional structure of a cavity-shape stack layer.

6. The multi-layer electric probe of claim 1, wherein the second strip layer covers at least a part of a surface of the first strip layer.

7. The multi-layer electric probe of claim 6, wherein the second strip layer covers substantially an entire surface of the first strip layer.

8. The multi-layer electric probe of claim 1, wherein the first strip layer has a round, triangular or polygonal cross-section.

9. The multi-layer electric probe of claim 1, wherein the first strip layer has a geometric shape cross-section.

10. The multi-layer electric probe of claim 1, wherein a material of the first strip layer and the second strip layer are selected from the group consisting of NiCo alloy, NiMn alloy, Cu, Ni, Au, Ag, Co, W, W alloy and Ni alloy.

11. The multi-layer electric probe of claim 1, wherein the desired mechanical strength is used for generating a required elasticity and deformation for testing.

12. The multi-layer electric probe of claim 1, wherein the desired conductivity is used for generating a required current.

13. The multi-layer electric probe of claim 1, wherein the first strip layer and the second strip layer have at least one curve portion.

14. The multi-layer electric probe of claim 1, wherein the first strip layer and the second strip layer are solidly adhered by an electro-forming process.

15. The multi-layer electric probe of claim 1, wherein the first strip layer and the second strip layer are solidly adhered by an electroplating process.

16. A multi-layer electric probe, suitable for testing a to-be-tested device, comprising:
a measuring section; and
a body section mechanically connected to the measuring section, wherein one end of the body section is used for contacting the to-be-tested device and applying at least one testing parameter,
wherein the body section at least comprises:
a first strip layer, having a first conductivity and a first mechanical strength; and
a second strip, having a second conductivity and a second mechanical strength, wherein the first strip layer and the second strip layer are solidly adhered to form a structural body so as to produce at least one of the desired capabilities of enduring current and mechanical strength.

17-19. (canceled)
